(19) United States
(12) Patent Application Publication
(10) Pub. No.: US 2017/0090000 A1
(43) Pub. Date: Mar. 30, 2017

(54) METHOD AND APPARATUS FOR DETECTING DYNAMIC MAGNETIC FIELD DISTRIBUTIONS

(71) Applicant: NATIONAL TAIWAN UNIVERSITY, Taipei (TW)

(72) Inventors: FA-HSUAN LIN, Taipei (TW); YING-HUA CHU, Taipei (TW); YI-CHENG HSU, Taipei (TW)

(21) Appl. No.: 14/925,273

(22) Filed: Oct. 28, 2015

(30) Foreign Application Priority Data
Sep. 30, 2015 (TW) 104132042

(51) Int. Cl. G01R 33/565; G01R 33/36; G01R 33/385

(52) U.S. Cl. CPC G01R 33/56563; G01R 33/385; G01R 33/3607

(57) ABSTRACT

A method for detecting dynamic magnetic field distributions is provided and includes: generating a dephasing gradient magnetic field and a rephasing gradient magnetic field, wherein the dephasing and rephasing gradient magnetic fields are generated after a radio frequency pulse has been generated, and the magnetic resonance signal of the signal source sample of a magnetic field detector is acquired after the dephasing gradient magnetic field has been generated, wherein the rephasing gradient magnetic field is generated after the magnetic resonance signal of the signal source sample of the magnetic field detector has been acquired but before a magnetic resonance signal of an imaging object is acquired. The magnetic resonance signal of the signal source sample of magnetic field detectors and the magnetic resonance signal of the imaging object are obtained without interferencing between each other. Magnetic resonance images of the imaging object are corrected according the dynamic magnetic field distribution.

### RELATED APPLICATIONS

This application claims priority to Taiwan Application Serial Number 104132042, filed on Sep. 30, 2015, which is incorporated by reference herein in its entirety.

### BACKGROUND OF THE INVENTION

Field of the Invention

The present invention relates to a technique of correcting nuclear magnetic resonance images and more particularly to a method and apparatus for detecting dynamic magnetic field distributions.

Description of the Prior Art

The process of nuclear magnetic resonance imaging is predisposed to errors because of dynamic magnetic field distributions. The dynamic magnetic field distributions result from the main magnetic field (B₀) drift caused by shim coil heating, eddy current caused by rapid switching of gradient coil, or subject's heart beating and respiration. Methods of characterizing such magnetic field drifts have been proposed, such as using specially designed pulse sequences. However, these pulse sequence methods can only characterize magnetic field distributions with up to the 1^{st}-order polynomial. Furthermore, the pulse sequence is not effective in measuring magnetic field distributions against time timely, dynamically and accurately.

Recently, a technique of measuring magnetic field distributions was proposed. This method uses multiple magnetic field detectors distributed over the outside of the imaging volume in order to measure local magnetic field strengths, which are later fitted to a higher-order polynomial, to characterize the instantaneous magnetic field distribution. A magnetic field detector has been implemented as a device combining a small radio-frequency receiving coil and a nuclear magnetic resonance active sample inside the coil. To ensure that a magnetic field detector measures only local magnetic resonance signal generated from the sample inside the detector without the interference of the magnetic resonance signal from the imaging object, the sample inside the magnetic field detector has been chosen such that magnetic resonance signals of different frequencies are generated by the imaging object and the sample inside the magnetic field detector. In practice, for proton (H¹) magnetic resonance imaging measurements, magnetic field detectors detects non-proton (such as F¹⁹) magnetic resonance signal elicited by the sample inside the magnetic field detector. This method has the disadvantage of losing signal-to-noise ratio (SNR), because the magnetic resonance signal generated by the sample inside the magnetic field detector is typically much weaker than that generated by the imaging object. Alternatively, magnetic field detectors can use a sample generating the magnetic resonance signal at the same frequency of the magnetic resonance signal elicited by the imaging object, if a shielding device on the magnetic field detector. However, shielding can cause difficulty in exciting the sample inside the magnetic field detector. The bulky size of the shielding also poses the difficulty to arrange multiple magnetic field detectors around the imaging object.

### SUMMARY OF THE INVENTION

In view of the aforesaid drawbacks of the prior art, the present invention provides a method for detecting dynamic magnetic field distributions. The method comprises the steps of: generating a radio frequency pulse and receiving a magnetic resonance signal of an imaging object; generating a dephasing gradient magnetic field and a rephasing gradient magnetic field; receiving magnetic resonance signal from the signal source sample of a magnetic field detector; obtaining dynamic magnetic field distributions based on a collection of magnetic resonance signals from signal source samples inside multiple magnetic field detectors; and correcting the magnetic resonance signal of the imaging object in accordance with the dynamic magnetic field distribution, wherein the dephasing gradient magnetic field and the rephasing gradient magnetic fields are generated after the radio frequency pulse has been generated, and the magnetic resonance signal of the signal source sample is acquired after the dephasing gradient magnetic field has been generated, wherein the rephasing gradient magnetic field is generated after the magnetic resonance signal of the signal source sample has been acquired by the magnetic field detector but before the magnetic resonance signal of the imaging object is acquired by the receiving coil of a radio frequency transceiver module, wherein the absolute value of the moment (the time integral of the strength of the gradient magnetic field) of dephasing gradient magnetic field equals the absolute value of the moment of rephrasing gradient magnetic field but the signs of these two gradient moments are opposite.

Regarding the method of the present invention, the step of generating the dephasing gradient magnetic field and the rephasing gradient magnetic field comprises generating the dephasing gradient magnetic field and the rephasing gradient magnetic field in at least one direction.

Regarding the method of the present invention, the step of receiving the magnetic resonance signal of the signal source sample of the magnetic field detector comprises receiving the magnetic resonance signal with a plurality of magnetic field detectors distributed over the surface of the imaging volume, wherein the magnetic field detectors each comprise a radio frequency receiving coil enclosing the signal source sample.

Regarding the method of the present invention, constituents of the signal source sample include proton.

The present invention further provides a method for detecting dynamic magnetic field distributions, comprising the steps of: generating a radio frequency pulse and receiving magnetic resonance signal from an imaging object; generating a dephasing gradient magnetic field; receiving a magnetic resonance signal of a signal source sample of a magnetic field detector; obtaining a dynamic magnetic field distribution based on the measured magnetic resonance signal of the signal source sample; and correcting the magnetic resonance signal of the imaging object based on estimated dynamic magnetic field distribution, wherein the dephasing gradient magnetic field is generated after the radio frequency pulse has been generated, and the magnetic resonance signal of the signal source sample is acquired after the dephasing gradient magnetic field has been generated, wherein the magnetic resonance signal of the imaging object is acquired after the magnetic resonance signal of the signal source sample has been acquired.

The present invention further provides an apparatus for detecting dynamic magnetic field distributions, comprising: a radio frequency-excited receiving module configured to generate a radio frequency pulse and receive a magnetic resonance signal of an imaging object; a gradient coil module configured to generate a dephasing gradient magnetic field and a rephasing gradient magnetic field; a magnetic field detector module comprising a plurality of magnetic field detectors disposed within an imaging space, wherein the magnetic field detectors each comprise a radio frequency receiving coil enclosing a signal source sample of the magnetic field detectors and are configured to receive the magnetic resonance signal of the signal source sample; and a computation unit module configured to obtain a dynamic magnetic field fluctuation in accordance with the magnetic resonance signal of the signal source sample and correct the magnetic resonance signal of the imaging object in accordance with the dynamic magnetic field fluctuation, wherein the dephasing gradient magnetic field and the rephasing gradient magnetic field are generated after the radio frequency pulse has been generated, and the magnetic resonance signal of the signal source sample is acquired after the dephasing gradient magnetic field has been generated, wherein the rephasing gradient magnetic field is generated after the magnetic resonance signal of the signal source sample has been acquired but before the magnetic resonance signal of the imaging object is acquired, wherein cumulative strength of gradient magnetic field of the dephasing gradient magnetic field equals cumulative strength of gradient magnetic field of the rephasing gradient magnetic field.

The present invention further provides an apparatus for detecting dynamic magnetic field distributions, comprising: a radio frequency transceiver module to transmit radio frequency pulses and to receive magnetic resonance signal of an imaging object; a gradient coil module configured to generate dephasing gradient magnetic field; a magnetic field detector module comprising a plurality of magnetic field detectors distributed over the surface of the imaging volume, wherein the magnetic field detectors each comprise a radio frequency receiving coil enclosing a signal source sample of the magnetic field detectors and are configured to receive the magnetic resonance signal of the signal source sample; and a computation unit module configured to obtain dynamic magnetic field distributions based on the measured magnetic resonance signal of the signal source sample and to correct the magnetic resonance signal of the imaging object based on the estimated dynamic magnetic field distributions, wherein the dephasing gradient magnetic field is generated after the radio frequency pulse has been generated, and the magnetic resonance signal of the signal source sample is acquired after the dephasing gradient magnetic field has been generated, wherein the magnetic resonance signal of the imaging object is acquired after the magnetic resonance signal of the signal source sample has been acquired.

All equivalent amendments or changes made by persons skilled in the art to the other additional features and advantages of the present invention without departing from the spirit and scope of the present invention should be covered by the claims of the present invention.

### BRIEF DESCRIPTION OF THE DRAWINGS

FIG. 1 shows a schematic view of an apparatus for detecting dynamic magnetic field distributions in an embodiment of the present invention;

FIG. 2A shows pulse sequence diagram for imaging using a spiral k-space trajectory according to the present invention;

FIG. 2B shows a k-space trajectory of the spiral imaging according to the present invention;

FIG. 3 shows graphs of coefficients for different spatial polynomials used to fit the measured magnetic field over time in an embodiment of the present invention;

FIG. 4 shows graphs of spectra of coefficients for different spatial polynomials used to fit the measured magnetic field over time in an embodiment of the present invention;

FIG. 5A shows estimated magnetic field distributions at different time in an embodiment of the present invention;

FIG. 5B shows maps of the signal-to-noise ratio over time using uncorrected magnetic resonance image and corrected magnetic resonance image in an embodiment of the present invention;

FIG. 6A shows diagram for imaging using a echo-planar imaging k-space trajectory according to the present invention; and

FIG. 6B shows k-space trajectory of the echo-planar imaging according to the present invention.

### DETAILED DESCRIPTION OF THE EMBODIMENTS

Embodiments of the present invention are described hereunder with reference to the accompanying drawings. The description below provides a thorough account of the subject matters of the present invention. The accompany drawings, which are indispensable to the elucidation of the present invention, illustrate the embodiments of the present invention. The subject matters of the present invention can be implemented variably; hence, the subject matters covered or claimed by the present invention should not be interpreted in a way to be restricted to the illustrative embodiments. The illustrative embodiments serve only a purpose of explaining the subject matters of the present invention. Therefore, after studying the disclosure presented herein, persons skilled in the art understand that the embodiments described hereunder are illustrative rather than restrictive of the appended claims and the objectives defined in accordance with the equivalent scope of the appended claims.

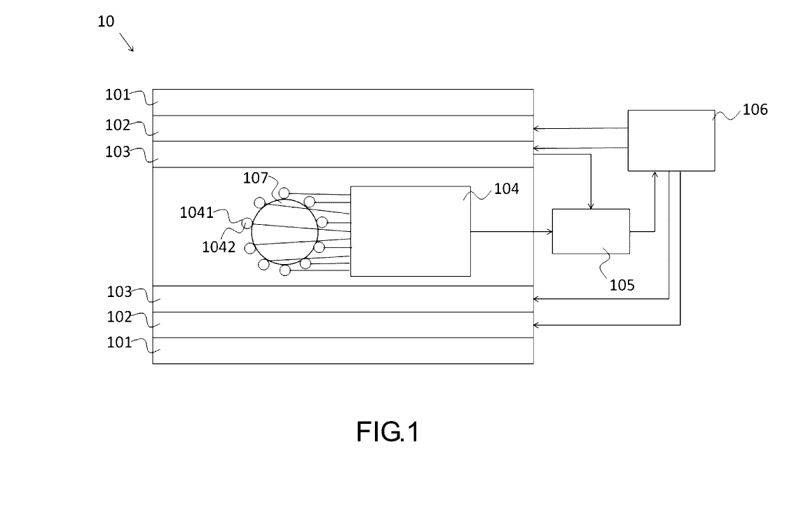

Referring to FIG. 1, there is shown a schematic view of an apparatus for detecting dynamic magnetic field distributions in an embodiment of the present invention. The present invention provides an apparatus 10 for detecting dynamic magnetic field distributions. The apparatus 10 comprises a magnet 101 configured to generate a main magnetic field, a gradient coil module 102 configured to generate a gradient magnetic field, a radio frequency transceiver module 103 configured to transmit radio frequency pulses and to receive magnetic resonance signal from an imaging object, a magnetic field detector module 104 configured to receive a magnetic resonance signal of a signal source sample of magnetic field detectors 1041, a computation unit module 105, and a system control unit 106. The magnetic field detector module 104 comprises ten magnetic field detectors 1041 distributed over the surface of the imaging volume 107, including but not limited to a human body. The magnetic field detectors 1041 each comprise a radio frequency receiving coil, which encloses a signal source sample 1042, wherein the small radio frequency receiving coil has a coil diameter which is less than 10 mm. The constituents of the signal source sample 1042 of the magnetic field detector module 104 include proton, as exemplified by water. In a preferred embodiment of the present invention, both the signal source sample 1042 and the small radio frequency receiving coil are enclosed by FC-40 fluorination solution to achieve uniform magnetic susceptibility. The magnetic field detector module 104 further comprises a decoupling PIN diode, a circuit matcher, and a low-noise amplifier to receive magnetic resonance signals of a signal source sample. In another embodiment of the present invention, the number of the magnetic field detectors is not necessarily 10.

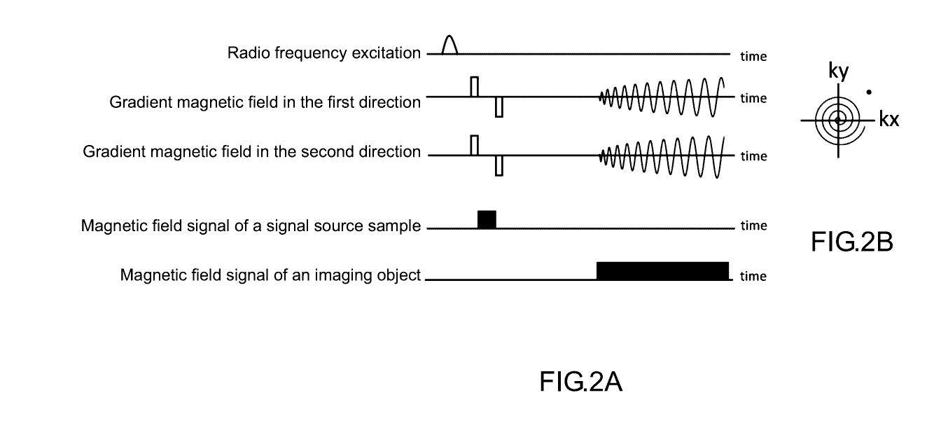

Referring to FIG. 2A, there is shown a schematic view of the pulse sequence applicable to spiral imaging according to the present invention. The system control unit 106 controls the timing of pulses generated by the radio frequency transceiver module 103 and the gradient coil module 102. In an embodiment of the present invention, the radio frequency transceiver module 103 generates a radio frequency pulse, and then the gradient coil module 102 generates dephasing gradient magnetic field along one direction and a dephasing gradient magnetic field along another direction. The reception of the magnetic resonance signal of a signal source sample is after the dephasing gradient magnetic field. The moment (time integral) of the gradient magnetic field of both dephasing gradient magnetic fields is predetermined such that the magnetic resonance signal from the imaging object is in a dephasing state. Hence, the strength of the magnetic resonance signal of the imaging object is minimal, and the magnetic resonance signal of a signal source sample, which is received by magnetic field detectors 1041, has the minimal contribution from the magnetic resonance signal from the imaging object. When the magnetic field detectors 1041 receive magnetic resonance signal of a signal source sample over time, the dynamic magnetic field distributions can be estimated with minimal interference by the magnetic resonance signal from the imaging object. Furthermore, after receiving the magnetic resonance signal of a signal source sample, the gradient coil module 102 generates rephasing gradient magnetic field along one direction and a rephasing gradient magnetic field along another direction. The moments of both resphasing gradient magnetic fields has the same absolute value as the moments of both dephasing gradient magnetic fields against time. But these two moments are opposite in signs, such that the magnetic resonance signal from the imaging object is no longer in a dephasing state (i.e., returning to the center of k-space). Afterward, the radio frequency transceiver module 103 receives the magnetic resonance signal of the imaging object. According to the present invention, the aforesaid signal acquisition and pulse sequence design entails using a gradient coil module to adjust and control the traversal of the k-space in a specific trajectory, such that the magnetic resonance signal of a signal source sample is measured at the periphery of the k-space in order to minimize the interference, as shown in FIG. 2B, and in consequence the magnetic resonance signal of the imaging object is in a dephasing state, thereby obtaining the dynamic magnetic field distributions with the minimal contribution from the magnetic resonance signal from the imaging object.

In a preferred embodiment of the present invention, we used the following pulse sequence parameters: TR=100 ms, α=30°, TE=30 ms, resolution=2 mm×2 mm×5 mm, with a slew rate of 110 T/m/s. It takes the computation unit module 105 9 ms to acquire the magnetic resonance signal generated by the signal source sample and received by the magnetic field detectors 1041. The moments of the dephasing and rephrasing gradient magnetic field along two directions were all 59 mTms/m. In another embodiment of the present invention, the gradient coil module 102 is not restricted to the generation of gradient magnetic field in two directions; instead, it is practicable for the gradient coil module 102 to generate gradient magnetic field in only one direction or in at least three directions, such that different moments of the gradient magnetic field cause the magnetic resonance signal of the imaging object in a dephasing state.

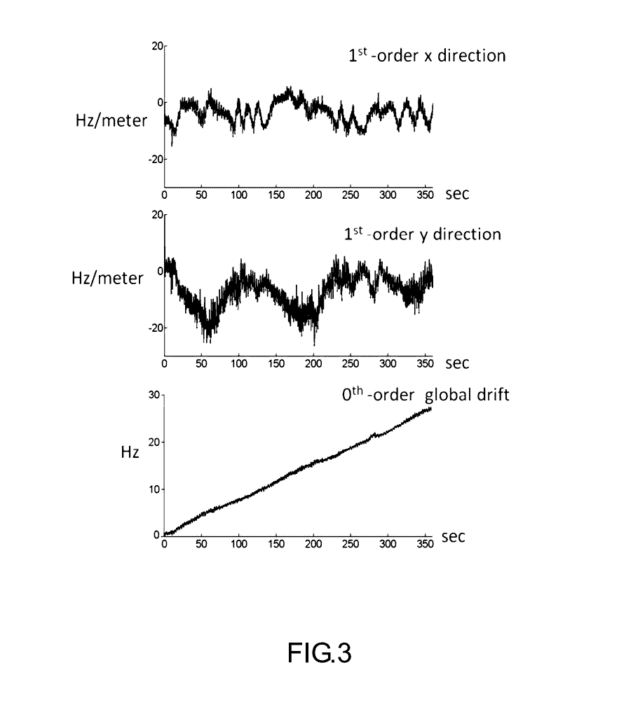

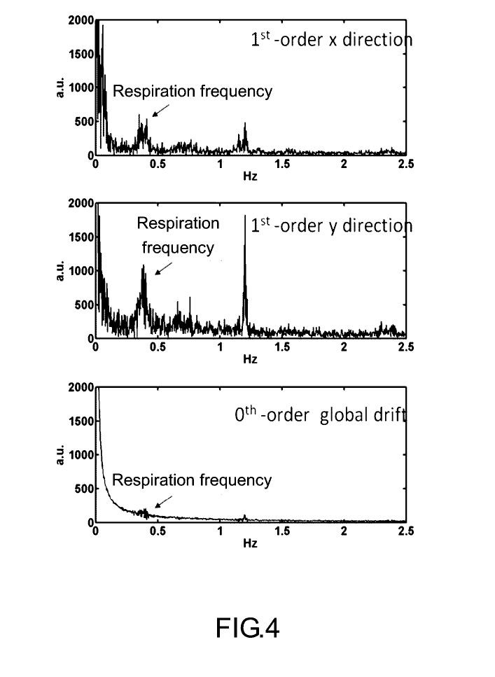

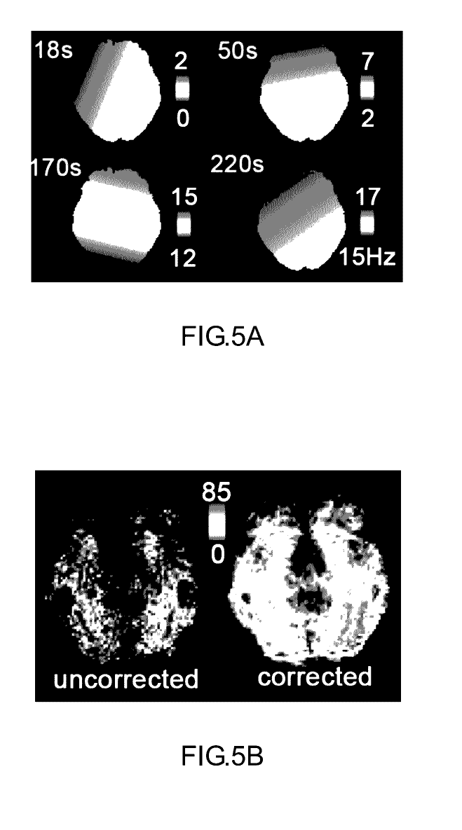

Referring to FIG. 1, the computation unit module 105 acquires magnetic resonance signal attributed to the signal source sample and received by the magnetic field detectors 1041. The computation unit module 105 converts the magnetic resonance signal of the signal source sample from an analog signal into a digital computable format. With space coordinates of magnetic field detectors, these data are used to estimate magnetic field distributions with a polynomial equation. Referring to FIG. 3, there are shown waveforms of the estimated coefficients for different polynomial terms in an embodiment of the present invention. As shown in the graphs, the 0^{th}-order magnetic field and the 1^{st}-order magnetic field gradients in the x direction and y direction are dynamically measured. Referring to FIG. 4, there are shown spectra of the 0^{th}-order magnetic field and the 1^{st}-order magnetic field gradients in the x direction and y direction in an embodiment of the present invention. Dynamic measurements of the magnetic resonance signal of a signal source sample can be used to estimate dynamic spatial magnetic field distributions. Referring to FIG. 5A, in an embodiment of the present invention, dynamic magnetic field distributions during 4-minute measurement are estimated at the 18^{th} second, the 50^{th} second, the 170^{th} second and the 220^{th} second. Referring to FIG. 1, the magnetic resonance signal of the imaging object, which have been received by the radio frequency transceiver module 103, is acquired by the computation unit module 105, and then the computation unit module 105 corrects the magnetic resonance signal of the imaging object based on the dynamic spatial magnetic field distributions, so as to reconstruct magnetic resonance images. Referring to FIG. 5B, there are shown pictures taken of an uncorrected magnetic resonance image and a corrected magnetic resonance image in an embodiment of the present invention, wherein the corrected magnetic resonance image outperforms the uncorrected magnetic resonance image in time-domain signal-to-noise ratio (SNR) by 137%.

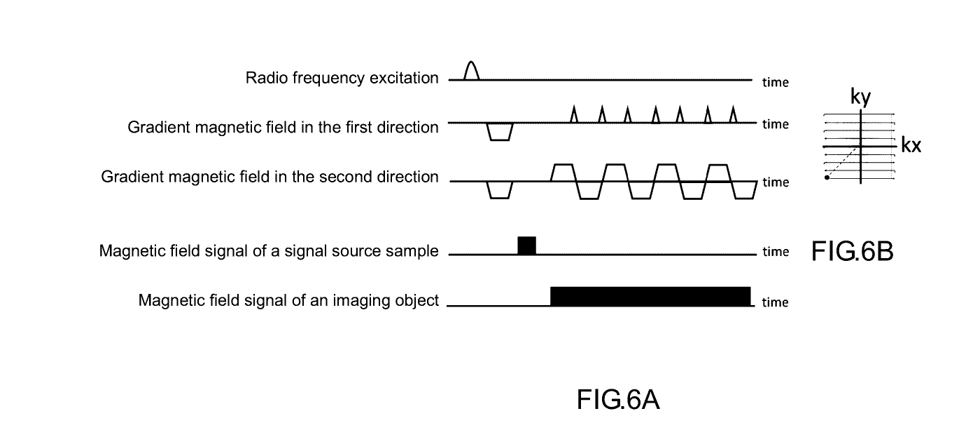

Referring to FIG. 6A, there are shown schematic view of the pulse sequence applicable to echo-planar imaging according to the present invention. The system control unit 106 controls the timing of pulses generated by the radio frequency transceiver module 103 and the gradient coil module 102. In an embodiment of the present invention, the radio frequency transceiver module 103 generates a radio frequency pulse, and then the gradient coil module 102 generates a dephasing gradient magnetic field along one direction and a dephasing gradient magnetic field along another direction. The reception of the magnetic resonance signal of a signal source sample is after the dephasing gradient magnetic field. The moments of the dephasing gradient magnetic field along two directions are predetermined, such that the magnetic resonance signal of the imaging object is in a dephasing state. Hence, the strength of the magnetic resonance signal of the imaging object is minimal, and the magnetic resonance signal of a signal source sample, which is received by the magnetic field detectors 1041, has the minimal contribution from the magnetic resonance signal from the imaging object. When the magnetic field detectors 1041 receive magnetic resonance signal of a signal source sample over time, dynamic magnetic field distributions with minimal contribution from the magnetic resonance signal from the imaging object can be obtained. Referring to FIG. 6B, there is shown a schematic view of k-space trajectory of echo-planar imaging according to the present invention. Since the process of gathering data in echo-planar imaging begins at the periphery of the k-space, the pulse sequence design and signal acquisition applicable to echo-planar imaging shown in FIG. 6A differ from the pulse sequence design and signal acquisition applicable to spiral imaging shown in FIG. 2 in that: the magnetic resonance signal of the imaging object returns to the center of the k-space no longer through the use of a rephasing gradient magnetic field, such that the magnetic resonance signal of the imaging object is acquired after the magnetic resonance signal of the signal source sample has been acquired.

The above description of preferred embodiments of the present invention enables persons skilled in the art to understand that various modifications and changes can be made to the preferred embodiments of the present invention without departing from the spirit and the appended claims, and understand that the present invention is not restricted to the ways of implementing the embodiments described in the specification.

What is claimed is:

1. A method for detecting dynamic magnetic field distributions, comprising the steps of:
generating a radio frequency pulse and receiving a magnetic resonance signal of an imaging object;
generating a dephasing gradient magnetic field and a rephasing gradient magnetic field;
receiving a magnetic resonance signal of a signal source sample of a magnetic field detector;
obtaining a dynamic magnetic field fluctuation in accordance with the magnetic resonance signal of the signal source sample; and
correcting the magnetic resonance signal of the imaging object in accordance with the dynamic magnetic field fluctuation,
wherein the dephasing gradient magnetic field and the rephasing gradient magnetic field are generated after the radio frequency pulse has been generated, and the magnetic resonance signal of the signal source sample is acquired after the dephasing gradient magnetic field has been generated, wherein the rephasing gradient magnetic field is generated after the magnetic resonance signal of the signal source sample has been acquired but before the magnetic resonance signal of the imaging object is acquired,
wherein the absolute value of the moment of dephasing gradient magnetic field equals the absolute value of the moment of rephasing gradient magnetic field, and these two moments are opposite in signs.

2. The method of claim 1, wherein the step of generating the dephasing gradient magnetic field and the rephasing gradient magnetic field comprises generating the dephasing gradient magnetic field and the rephasing gradient magnetic field in at least a direction with a gradient coil.

3. The method of claim 1, wherein the step of receiving the magnetic resonance signal of the signal source sample of the magnetic field detector comprises receiving the magnetic resonance signal with a plurality of magnetic field detectors distributed over a surface of an imaging volume, wherein the magnetic field detectors each comprise a radio frequency receiving coil enclosing the signal source sample.

4. The method of claim 1, wherein constituents of the signal source sample include proton.

5. A method for detecting dynamic magnetic field distributions, comprising the steps of:
generating a radio frequency pulse and receiving a magnetic resonance signal of an imaging object;
generating a dephasing gradient magnetic field;
receiving a magnetic resonance signal of a signal source sample of a magnetic field detector;
obtaining a dynamic magnetic field fluctuation in accordance with the magnetic resonance signal of the signal source sample; and
correcting the magnetic resonance signal of the imaging object in accordance with the dynamic magnetic field fluctuation,
wherein the dephasing gradient magnetic field is generated after the radio frequency pulse has been generated, and the magnetic resonance signal of the signal source sample is acquired after the dephasing gradient magnetic field has been generated, wherein the magnetic resonance signal of the imaging object is acquired after the magnetic resonance signal of the signal source sample has been acquired.

6. The method of claim 5, wherein the step of generating the dephasing gradient magnetic field comprises generating the dephasing gradient magnetic field in at least a direction with a gradient coil.

7. The method of claim 5, wherein the step of receiving the magnetic resonance signal of the signal source sample of the magnetic field detector comprises receiving the magnetic resonance signal with a plurality of magnetic field detectors distributed over a surface of an imaging volume, wherein the magnetic field detectors each comprise a radio frequency receiving coil enclosing the signal source sample.

8. The method of claim 5, wherein constituents of the signal source sample include proton.

9. An apparatus for detecting dynamic magnetic field distributions, comprising:
a radio frequency transceiver module configured to generate a radio frequency pulse and to receive a magnetic resonance signal of an imaging object;
a gradient coil module configured to generate a dephasing gradient magnetic field and a rephasing gradient magnetic field;
a magnetic field detector module comprising a plurality of magnetic field detectors distributed over a surface of an imaging volume, wherein the magnetic field detectors each comprise a radio frequency receiving coil enclosing a signal source sample of the magnetic field detectors and are configured to receive the magnetic resonance signal of the signal source sample; and
a computation unit module configured to obtain a dynamic magnetic field fluctuation in accordance with the magnetic resonance signal of the signal source sample and to correct the magnetic resonance signal of the imaging object in accordance with the dynamic magnetic field fluctuation,
wherein the dephasing gradient magnetic field and the rephasing gradient magnetic field are generated after the radio frequency pulse has been generated, and the magnetic resonance signal of the signal source sample is acquired after the dephasing gradient magnetic field has been generated, wherein the rephasing gradient magnetic field is generated after the magnetic resonance signal of the signal source sample has been acquired but before the magnetic resonance signal of the imaging object is acquired,
wherein the absolute value of the moment of the dephasing gradient magnetic field equals the absolute value of the moment of the rephrasing gradient magnetic field, and these two moments are opposite in signs.

10. The apparatus of claim 9, wherein the gradient coil module comprises gradient coils generating gradient magnetic field distributions in at least three directions and generates the dephasing gradient magnetic field and the rephasing gradient magnetic field in at least one direction with one gradient coil.

11. The apparatus of claim 9, wherein constituents of the signal source sample include proton.

12. An apparatus for detecting dynamic magnetic field distributions, comprising:
a radio frequency transceiver module configured to generate a radio frequency pulse and to receive a magnetic resonance signal of an imaging object;
a gradient coil module configured to generate a dephasing gradient magnetic field;
a magnetic field detector module comprising a plurality of magnetic field detectors distributed over a surface of an imaging volume, wherein the magnetic field detectors each comprise a radio frequency receiving coil enclosing a signal source sample of the magnetic field detectors and are configured to receive the magnetic resonance signal of the signal source sample; and
a computation unit module configured to obtain a dynamic magnetic field fluctuation in accordance with the magnetic resonance signal of the signal source sample and to correct the magnetic resonance signal of the imaging object in accordance with the dynamic magnetic field fluctuation,
wherein the dephasing gradient magnetic field is generated after the radio frequency pulse has been generated, and the magnetic resonance signal of the signal source sample is acquired after the dephasing gradient magnetic field has been generated, wherein the magnetic resonance signal of the imaging object is acquired after the magnetic resonance signal of the signal source sample has been acquired.

13. The apparatus of claim 12, wherein the gradient coil module comprises gradient coils generating gradient magnetic field distributions in at least three directions and generates the dephasing gradient magnetic field in at least one direction with one gradient coil.

14. The apparatus of claim 12, wherein constituents of the signal source sample include proton.
